(19) United States
(12) Patent Application Publication
(10) Pub. No.: US 2026/0036703 A1
(43) Pub. Date: Feb. 5, 2026

(54) RADIATION DETECTOR AND RADIATION IMAGING APPARATUS

(71) Applicant: CANON KABUSHIKI KAISHA, Tokyo (JP)

(72) Inventors: RYOSUKE MIURA, Chiba (JP); JUN KAWANABE, Saitama (JP); TAKANORI TAYA, Kanagawa (JP); MISAKI KOSUGI, Saitama (JP); YUKI IWABUCHI, Kanagawa (JP); TOMOYUKI YAGI, Tokyo (JP)

(21) Appl. No.: 19/279,875

(22) Filed: Jul. 24, 2025

(30) Foreign Application Priority Data
Jul. 30, 2024 (JP) 2024-123114
Sep. 6, 2024 (JP) 2024-154233
Mar. 13, 2025 (JP) 2025-040486

(51) Int. Cl. G01T 1/20; H10F 39/00; H10F 39/18

(52) U.S. Cl. CPC G01T 1/2018; H10F 39/1898; H10F 39/803; H10F 39/811

(57) ABSTRACT

A radiation detector includes a pixel matrix a plurality of first drive lines for driving, and a plurality of second drive lines, wherein a first pixel row of the pixel matrix is a pixel row that is neighbored by the first drive line and also by the second drive line, wherein an average area of an opening portion of the image capturing pixel included in the first pixel row and an opening portion of the detection pixel is a first average area, and wherein an error of an area of each opening portion of all image capturing pixels and all detection pixels included in the first pixel row falls within 1% of the first average area.

### BACKGROUND

### Field of the Technology

The present disclosure relates to a radiation detection sensor. A radiation imaging apparatus including a radiation detection sensor is an apparatus that is used as a medical diagnosis device or a nondestructive inspection device, and is used, for example, as an X-ray flat panel detector.

### Description of the Related Art

In radiation imaging apparatuses that acquire radiographic images based on radiation, there has been conventionally known a technique of measuring a dose of radiation entering a radiation imaging apparatus during radiation imaging, and using the dose for image capturing control. Examples of such a technique include an automatic exposure control (AEC) function. By using the AEC function, it is possible to reduce an exposure dose of a subject in radiation imaging.

Japanese Patent No. 4659337 discusses a radiation imaging apparatus having an AEC function. The radiation imaging apparatus discussed in Japanese Patent No. 4659337 is provided with a routing wiring line to be connected to a photoelectric conversion element for monitoring, as an additional wiring line, aside from a gate line to be connected to a photoelectric conversion element for image capturing.

In a case where an additional wiring line is provided in a partial region of a pixel matrix as in Japanese Patent No. 4659337, pixels positioned near the additional wiring line are subject to restriction in arrangement of opening portions. Because disarrangement of opening portions partially in the pixel matrix can lead to image disturbance, it is desirable that pixels and wiring lines be arranged in an appropriate layout.

### SUMMARY

The present disclosure has been devised in view of the above-described issues, and the present disclosure is directed to providing a radiation detection sensor in which pixels and wiring lines are appropriately arranged.

The present disclosure is also directed to a radiation detector including a pixel matrix including a plurality of pixels arranged in a matrix, each including a conversion element that converts radiation or light into a charge, and a switch element, the pixel matrix including a plurality of image capturing pixels to be used for acquisition of a radiographic image, and a plurality of detection pixels to be used for detection of a dose of radiation, a plurality of first drive lines for driving switch elements of the plurality of image capturing pixels, the plurality of first drive lines extending along a row direction of the matrix, and a plurality of second drive lines for driving switch elements of the plurality of detection pixels, the plurality of second drive lines extending along the row direction, wherein a first pixel row of the pixel matrix is a pixel row that is neighbored by the first drive line and also by the second drive line, wherein an average area of an opening portion of the image capturing pixel included in the first pixel row and an opening portion of the detection pixel is a first average area, and wherein an error of an area of each opening portion of all image capturing pixels and all detection pixels included in the first pixel row falls within 1% of the first average area.

According to an aspect of the present disclosure, a radiation detection sensor includes a pixel matrix in which a plurality of pixels, each including a conversion element that converts radiation or light into a charge, and a switch element, is arranged in a matrix, the pixel matrix including a plurality of image capturing pixels to be used for acquisition of a radiographic image, and a plurality of detection pixels to be used for detection of a dose of radiation, a first drive line for driving a switch element of the image capturing pixel included in a first row of the pixel matrix, and a second drive line for driving a switch element of the detection pixel included in the first row of the pixel matrix, in which a second row different from the first row neither includes the detection pixel nor the second drive line, and an opening portion of a plurality of image capturing pixels with a first shape corresponding to all image capturing pixels included in the first row has a smaller area than an opening portion of an image capturing pixel with a second shape included in the second row.

Features of the present disclosure will become apparent from the following description of embodiments with reference to the attached drawings. The following description of embodiments is described by way of example.

### BRIEF DESCRIPTION OF THE DRAWINGS

FIG. 1 is a diagram illustrating a configuration of a radiation imaging system including a radiation imaging apparatus.

FIG. 2 is a diagram illustrating a configuration of a radiation imaging apparatus.

FIG. 3 is a plan view illustrating a pixel.

FIG. 4 is a plan view illustrating a pixel matrix according to a first exemplary embodiment.

FIG. 5 is a cross-sectional view illustrating a pixel.

FIG. 6 is a plan view illustrating a pixel matrix according to a second exemplary embodiment.

FIG. 7 is a plan view illustrating a pixel matrix according to a third exemplary embodiment.

FIG. 8 is a plan view illustrating a pixel matrix according to a fourth exemplary embodiment.

FIG. 9 is a plan view illustrating a pixel matrix according to a fifth exemplary embodiment.

FIG. 10 is a cross-sectional view illustrating a pixel.

FIG. 11 is a diagram illustrating a configuration example of an amplifying unit of the radiation imaging apparatus in FIG. 2.

FIG. 12 is a diagram illustrating a drive example of the radiation imaging apparatus in FIG. 2.

FIG. 13 is a timing chart illustrating a drive example of the radiation imaging apparatus in FIG. 2.

FIG. 14 is a timing chart illustrating a drive example of the radiation imaging apparatus in FIG. 2.

### DESCRIPTION OF THE EMBODIMENTS

Hereinafter, exemplary embodiments of the present disclosure will be described in detail using examples. In the exemplary embodiments, the same reference numerals are given to identical elements, and the description thereof will not be repeated. Further, configurations described in the respective exemplary embodiments may be changed or combined as appropriate.

### <Radiation Imaging System>

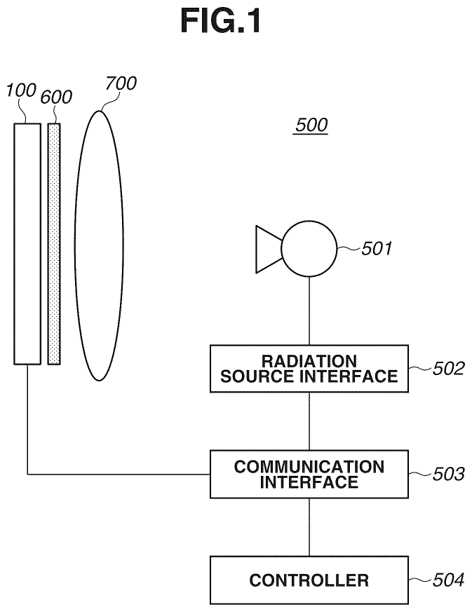

FIG. 1 illustrates a configuration example of a radiation imaging system 500 including a radiation imaging apparatus 100. The radiation imaging system 500 includes the radiation imaging apparatus 100 (radiation detection apparatus, radiation imaging apparatus), a radiation source 501, a radiation source interface 502, a communication interface 503, a controller 504, a grid 600, and a subject 700. FIG. 1 illustrates an example in which the radiation imaging apparatus 100 and the radiation source 501 (radiation generation apparatus) communicate with each other via a cable, but the radiation imaging apparatus 100 and the radiation source 501 may wirelessly communicate with each other. The grid 600 is a component arranged to remove scattered radiation. The grid 600 may not be used depending on an imaging content.

In radiation imaging, first, image capturing information such as a dose, an irradiation time (ms), a tube current (mA), a tube voltage (kV), and an light field being a region where radiation is detected is input to the controller 504. Next, if an exposure switch attached to the radiation source 501 is operated, the controller 504 transmits a start request signal to the radiation imaging apparatus 100. The start request signal is a signal that requests a start of radiation emission. Upon receiving the start request signal, the radiation imaging apparatus 100 starts preparation for receiving emitted radiation. When the preparation is completed, the radiation imaging apparatus 100 transmits a ready-to-start signal to the radiation source interface 502 via the communication interface 503. The ready-to-start signal is a signal for notifying that the radiation emission can be started. Upon receiving the ready-to-start signal, the radiation source interface 502 causes the radiation source 501 to start radiation emission.

The radiation imaging apparatus 100 detects a dose of the emitted radiation, and when an integrated value of the dose reaches a target threshold, the radiation imaging apparatus 100 transmits a stop notification to the radiation source interface 502 via the communication interface 503. The stop notification is a signal that requests an end of radiation emission. Upon receiving the stop notification, the radiation source interface 502 causes the radiation source 501 to end the radiation emission. The target threshold of the dose is determined based on a dose input value, radiation emission intensity, and communication delay and processing delay between units.

### <Radiation Imaging Apparatus>

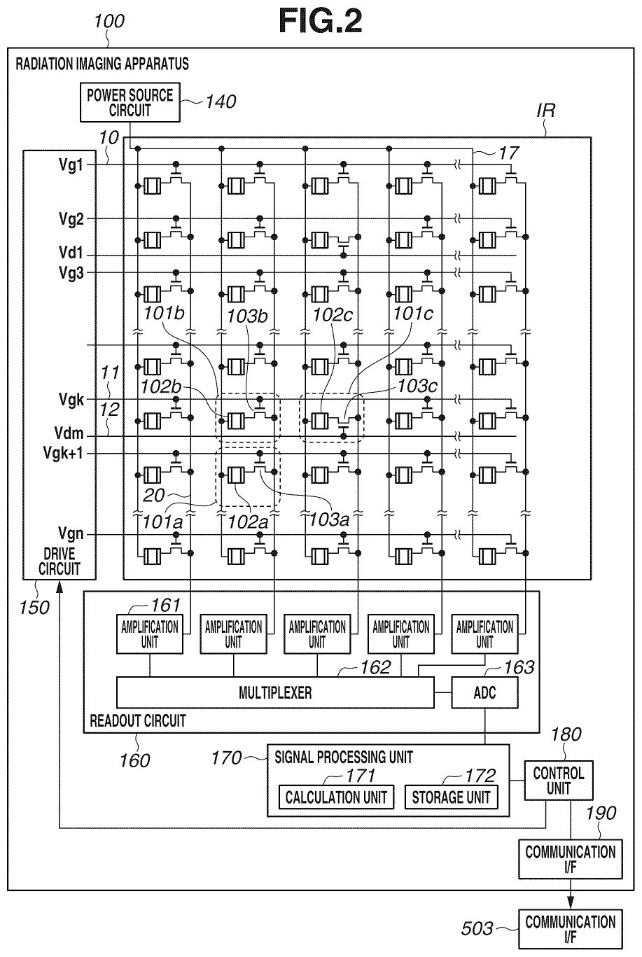

FIG. 2 illustrates a configuration example of the radiation imaging apparatus 100. The radiation imaging apparatus 100 includes a radiation detection sensor IR (radiation detection panel) corresponding to an image capturing region, a drive circuit 150, a readout circuit 160, a signal processing unit 170, a control unit 180, and a communication interface (I/F) 190.

The radiation detection sensor IR includes a plurality of pixels arrayed in a matrix (pixel matrix) in such a manner as to include a plurality of rows and a plurality of columns, a plurality of drive lines 10, 11, and 12, and a plurality of signal lines 20. The plurality of drive lines 10, 11, and 12 are arranged in corresponding rows in the pixel matrix.

In other words, at least one of the drive lines 10, 11, and 12 is arranged in each row of the pixel matrix. The plurality of signal lines 20 is arranged corresponding to a plurality of columns of pixels. In other words, the columns of the respective signal lines 20 each correspond to one pixel column.

The pixel matrix of the radiation detection sensor IR includes a plurality of pixels of multiple types. The pixels of the multiple types include a first image capturing pixel 101a used to acquire a radiographic image, and one or more detection pixels 101c (detection elements) used to detect an irradiation amount of radiation. The pixels of the multiple types also include a plurality of second image capturing pixels 101b that is arranged in the same row as the detection pixels 101c and used to acquire a radiographic image.

The first image capturing pixel 101a includes a conversion element 102a that converts radiation into an electrical signal, and a switch element 103a that connects a corresponding signal line 20 and the conversion element 102a. Each second image capturing pixel 101b includes a conversion element 102b that converts radiation into an electrical signal, and a switch element 103b that connects a corresponding signal line 20 and the conversion element 102b.

Each detection pixel 101c includes a conversion element 102c that converts radiation into an electrical signal, and a switch element 103c that connects a corresponding signal line 20 and the conversion element 102c.

Here, a large part of the pixel matrix is constituted of image capturing pixels (image capturing pixels 101a and 101b), and the detection pixels 101c are arranged with spacing and isolation so as to blend in with the image capturing pixels.

The conversion elements 102a, 102b, and 102c each include, for example, a scintillator that converts radiation into light, and a photoelectric conversion element that converts light into an electrical signal. The scintillator is formed into a sheet shape so as to cover the pixel matrix. In place of the above-described configuration, the conversion elements 102a, 102b, and 102c may each include a conversion element that directly converts radiation into an electrical signal.

The switch elements 103a, 103b, and 103c can each include, for example, a thin-film transistor (TFT) in which an active region is made of a semiconductor such as amorphous silicon or polycrystal silicon. Nevertheless, the switch elements 103a, 103b, and 103c are not limited thereto, and appropriate elements may be used as the switch elements 103a, 103b, and 103c as long as the elements can control connection or disconnection between the conversion elements 102a, 102b, and 102c and the signal lines 20.

A first electrode of the conversion element 102a is connected to a first main electrode of the switch element 103a, and a second electrode of the conversion element 102a is connected to a bias line 17. One bias line 17 extends in a column direction, and is connected in common to second electrodes of a plurality of conversion elements 102a arrayed in the column direction. The bias line 17 receives a bias voltage Vs from a power source circuit 140. A second main electrode of each switch element 103a of one or more first image capturing pixels 101a included in one column is connected to one signal line 20. A control electrode of each switch element 103a of one or more first image capturing pixels 101a included in one row is connected to one drive line 10. The second image capturing pixel 101b is connected to the second drive line 11. The detection pixel 101c is connected to the detection drive line 12. Here, in a predetermined row, the second drive line 11 connects to the second image capturing pixel 101b from one side, and the detection drive line 12 connects to the detection pixel 101c from the other side (opposite side). In the predetermined row, a plurality of detection pixels 101c may be arranged.

The drive circuit 150 is a circuit configured to supply a drive signal to a pixel to be driven through the plurality of drive lines 10, 11, and 12 in accordance with a control signal from the control unit 180. The drive lines 10 and 11 to which image capturing pixels are connected, and the detection drive line 12 to which detection pixels are connected may be connected to different drive circuits. Specifically, the drive lines 10 and 11 may be connected to a drive circuit for image capturing, and the detection drive line 12 may be connected to a drive circuit for dose detection. In a first exemplary embodiment, the drive signal is a signal for turning on a switch element included in a pixel to be driven. The switch element of each pixel is turned on by a high-level signal and turned off by a low-level signal. Here, the high-level signal is referred to as a drive signal. When the drive signal is supplied to a pixel, a signal accumulated in a conversion element of the pixel becomes a state of being able to be read by the readout circuit 160. In the configuration illustrated in FIG. 2, pluralities of drive lines 10 and 11 that drive the image capturing pixels 101a and 101b, and a plurality of drive lines 12 that drive the detection pixels 101c are connected to the same drive circuit 150. Nevertheless, the configuration is not limited thereto. A drive circuit that drives the pluralities of drive lines 10 and 11 connected to the image capturing pixels 101a and 101b, and a drive circuit that drives the plurality of drive lines 12 connected to the detection pixels 101c may be separately arranged. More specifically, the drive circuit 150 may include a first drive circuit to which the pluralities of drive lines 10 and 11 are connected, and a second drive circuit to which the plurality of drive lines 12 is connected. In addition, the drive circuit 150 supplying a drive signal to a pixel will be sometimes expressed as the drive circuit 150 driving the drive lines 10, 11, and 12.

The readout circuit 160 is a circuit configured to read out signals from a plurality of pixels through a plurality of signal lines 20. The readout circuit 160 includes a plurality of amplifying units 161, a multiplexer 162, and an analog-to-digital converter (hereinafter, AD converter) 163. Each of the plurality of signal line 20 is connected to a corresponding amplifying unit 161 of the plurality of amplifying units 161 of the readout circuit 160. One signal line 20 corresponds to one amplifying unit 161. The multiplexer 162 selects each of the plurality of amplifying units 161 in a predetermined order, and supplies a signal from each selected amplifying unit 161 to the AD converter 163. The AD converter 163 converts the supplied signal into a digital signal, and outputs the digital signal. A plurality of detection pixels 101c arranged in different rows may be connected to the same signal line, and the readout circuit 160 may read out signals from the signal line.

Signals read out from the image capturing pixels 101a and 101b are supplied to the signal processing unit 170, and processing such as calculation and storing is performed by the signal processing unit 170. Specifically, the signal processing unit 170 includes a calculation unit 171 and a storage unit 172. The calculation unit 171 generates a radiographic image based on the signals read out from the image capturing pixels 101a and 101b, and supplies the generated radiographic image to the control unit 180.

Meanwhile, because no image capturing pixel exists at coordinates where the detection pixel 101c is positioned, a defect appears on a radiographic image. For this reason, when a radiographic image is generated, processing of complementing the defect using signals from first and second image capturing pixels located near the defect is performed. Signals read out from the detection pixels 101c are supplied to the signal processing unit 170, and processing such as calculation and storing is performed by the calculation unit 171. Specifically, the signal processing unit 170 outputs information indicating emission of radiation toward the radiation imaging apparatus 100 based on the signals read out from the detection pixels 101c. For example, the signal processing unit 170 detects the emission of radiation toward the radiation imaging apparatus 100, and determines an irradiation amount and/or an integrated irradiation amount of radiation.

The control unit 180 is a controller that controls the drive circuit 150 and the readout circuit 160 based on the information from the signal processing unit 170. The control unit 180 comprehensively controls the radiation imaging apparatus 100. The control unit 180 includes a central processing unit (CPU) serving as an arithmetic processing circuit, and a read-only memory (ROM) and a random access memory (RAM) serving as a memory. The control unit 180 implements various types of control, for example, by loading a program stored in the ROM into the RAM and causing the CPU to execute the program,. Alternatively, the control unit 180 may use a micro processing unit (MPU) or an application specific integrated circuit (ASIC) as a arithmetic processing circuit in place of the CPU. Based on the information from the signal processing unit 170, the control unit 180 controls, for example, a start and an end of exposure (accumulation of charges corresponding to radiation emitted by the image capturing pixels 101a and 101b).

To determine an irradiation amount of radiation, by controlling the drive circuit 150, the control unit 180 scans only the detection drive line 12 during the emission of radiation, so that only signals of the detection pixel 101c are in a readable state. Next, by controlling the readout circuit 160, the control unit 180 reads out a signal from a column corresponding to the detection pixel 101c, and outputs the signal as information indicating an irradiation amount of radiation. Through such an operation, the radiation imaging apparatus 100 can obtain irradiation information with respect to the detection pixel 101c during radiation emission. One or more detection pixels 101c and one or more detection drive lines 12 are arranged in a predetermined row in a light field that is a region where radiation is detected. One or more light fields are arranged in an image capturing region, and in a case where a plurality of light fields is arranged, a light field suitable for image capturing is selected.

By driving the detection drive lines 12 within the selected light field, it is possible to read out signals of the detection pixel 101c and detect an amount of radiation emitted to the selected light field.

### <Arrangement of Pixel and Wiring Line>

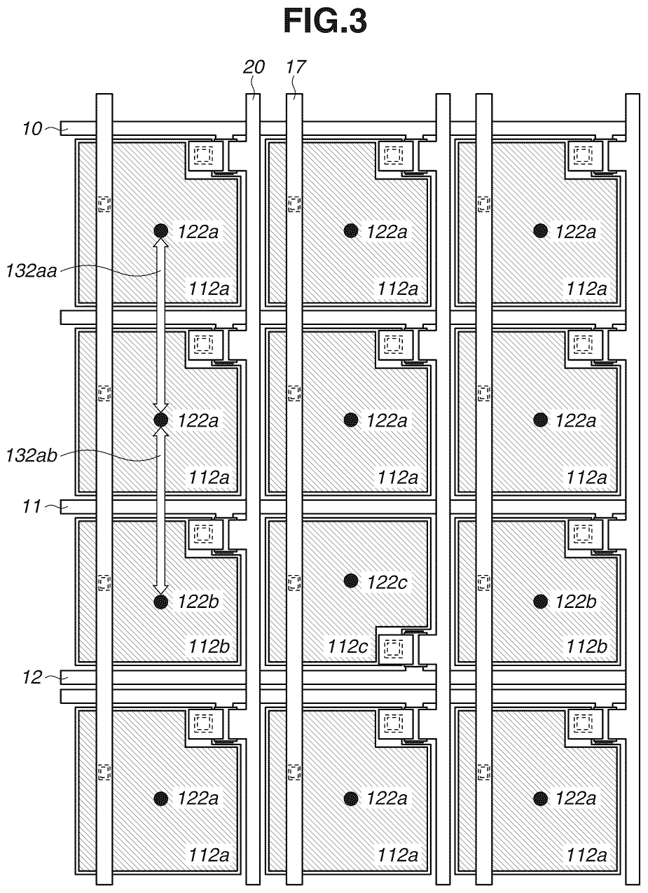

FIG. 3 is a plan view illustrating pixels. Each pixel includes a conversion element, and a bias line exists above the conversion element. An upper electrode of the conversion element and the bias line are connected. Opening portions 112a, 112b, and 112c that are regions where radiation or light converted from radiation can be detected are regions (portions) of the conversion elements that are not shielded by the bias lines. In other words, the bias line functions as a light shielding portion. The opening portion 112a is an opening portion of the first image capturing pixel 101a, the opening portion 112b is an opening portion of the second image capturing pixel 101b, and the opening portion 112c is an opening portion of the detection pixel 101c. In FIG. 3, regions of the opening portions are indicated by hatched lines. As described above, when radiation is emitted toward an opening portion, a charge corresponding to an amount of incident radiation is accumulated in a pixel, and the magnitude of the charge appears in an image as the density of the pixel. For this reason, it is desirable that areas of opening portions of all image capturing pixels be uniform. Here, the drive lines 10 and 11, which are connected to image capturing pixels such as the first image capturing pixel 101a and the second image capturing pixel 101b, are arranged at an equal pitch. In other words, a width (vertical width) of an arrangement region generated between two drive lines is uniform. Similarly, the signal lines 20 connected to the pixels are arranged at an equal pitch. In other words, a width (horizontal width) of an arrangement region generated between two signal lines is uniform. Nevertheless, in the row (predetermined row) in which the detection pixel 101c is arranged, the shape of an opening portion of the second image capturing pixel 101b arranged in the same row as the detection pixel 101c is affected by the size of an arrangement region of the detection drive line 12. Specifically, the shape (first shape) of the opening portion 112b of the second image capturing pixel 101b becomes smaller than the shape (second shape) of the opening portion 112a of the first image capturing pixel 101a.

In the present exemplary embodiment, the detection pixel 101c including the opening portion 112c that is about the same size as the opening portion 112b of the second image capturing pixel 101b is provided. At this time, in the row including the detection pixel 101c, the second drive line 11 is connected to the second image capturing pixel 101b from one side, and the detection drive line 12 is connected to the detection pixel 101c from the other side (opposite side). With such a configuration, it is possible to efficiently secure areas of the opening portions of the second image capturing pixel 101b and the detection pixel 101c. For this reason, it is possible to make an amount of charge accumulated in the second image capturing pixel 101b closer to an amount of charge accumulated in the first image capturing pixel 101a, and thereby preventing image disturbance. In the present exemplary embodiment, only one of the image capturing pixel and the detection pixel is arranged in one arrangement region (pixel space) without mixing the image capturing pixel and the detection pixel in one arrangement region (pixel space). For this reason, it is possible to secure sufficient sizes of the opening portions of the second image capturing pixel 101b and the detection pixel 101c. It is desirable that an area (average area) of the opening portion 112b of the second image capturing pixel 101b be 80% or more of an area (average area) of the opening portion 112a of the first image capturing pixel 101a. Similarly, it is desirable that an area (average area) of the opening portion 112c of the detection pixel 101c be 80% or more of an area (average area) of the opening portion 112a of the first image capturing pixel 101a.

In the present exemplary embodiment, all image capturing pixels arranged in the same row as the detection pixel 101c are uniformly formed as the second image capturing pixels 101b. In this manner, by preventing image capturing pixels with different areas of opening portions from being mixed in the same row, it is possible to prevent image disturbance.

It is desirable that areas of opening portions 112b of the second image capturing pixels 101b arranged in the same row be approximately equal. Specifically, an error of the area of each opening portion 112b desirably falls within 1% of an average value of areas of the opening portions 112b in the same row, and the error more desirably falls within 0.1% of the average value.

It is desirable that areas of opening portions 112c of the detection pixels 101c arranged in the same row be approximately equal. Specifically, an error of the area of each opening portion 112c desirably falls within 1% of an average value of areas of the opening portions 112c in the same row, and the error more desirably falls within 0.1% of the average value.

Furthermore, it is desirable that the average value (average area) of the areas of the opening portions 112b of the second image capturing pixels 101b arranged in the same row and the average value of the areas of the opening portions 112c of the detection pixels 101c are approximately equal. Specifically, an error of the average value of the areas of the opening portions 112c included in the same row desirably falls within 1% of the average value of areas of the opening portions 112b in the same row, and the error more desirably falls within 0.1% of the average value.

### <Modified Example>

The description has been provided with reference to FIG. 3 assuming that line widths of the drive lines 10, 11, and 12 are the same.

In a modified example, an example in which the drive line 12 has a line width thinner than the line widths of the drive lines 10 and 11 will be described.

In the row (predetermined row) in which the detection pixel 101c and the detection drive line 12 are arranged, the shape of the opening portion 112b of the second image capturing pixel 101b arranged in the same row as the detection pixel 101c is affected by the size of the arrangement region of the detection drive line 12. Specifically, the opening portion 112b of the second image capturing pixel 101b becomes small depending on an area of the region where the detection drive line 12 is arranged. For this reason, it is desirable that the line width of the detection drive line 12 be thinner and the shape of the opening portion 112b of the second image capturing pixel 101b be larger.

When the opening portion 112b of the second image capturing pixel 101b becomes smaller due to an influence of the detection drive line 12, as compared with the first image capturing pixel 101a, a centroid is shifted upward in a signal line direction (in a direction of the nearest drive lines 10 and 11). More specifically, the opening portion 112b of the second image capturing pixel 101b differs in shape from the opening portion 112a of the first image capturing pixel 101a, and the positions of centroids 122a and 122b of the opening portions differ between the neighboring drive lines 10 and 11 in the signal line direction (predetermined column direction). In other words, a distance 132aa between the centroids in the signal line direction of the opening portions of a plurality of first image capturing pixels 101a, and a distance 132ab between the centroids in the signal line direction of the neighboring first and second image capturing pixels are different near the second image capturing pixel 101b. When distances between the centroids of the opening portions of the image capturing pixels are different, moire occurs in a case where an image of a periodical structure such as a grid is captured, and image quality is affected. For this reason, it is desirable that the two distances between the centroids be closer.

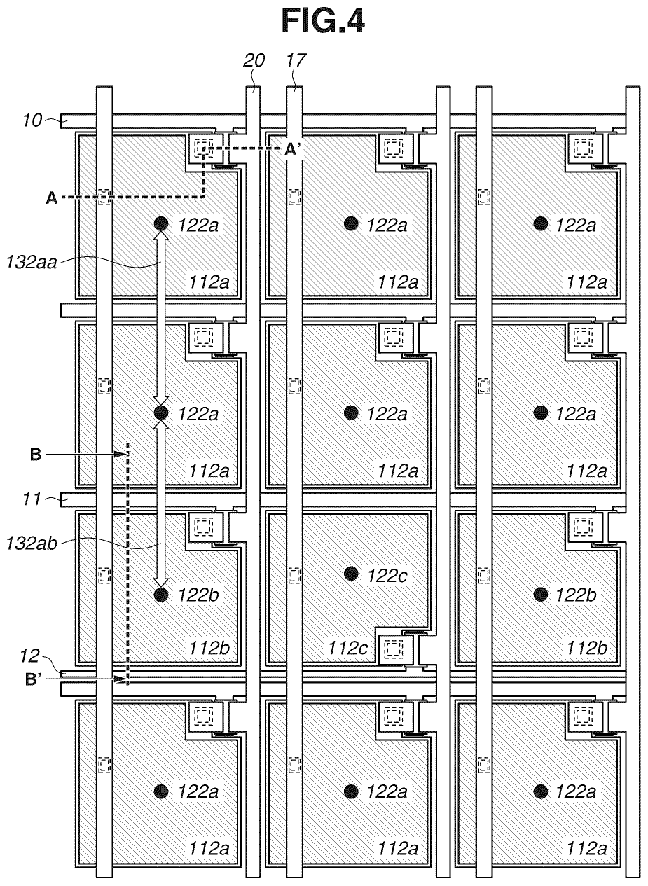

FIG. 4 is a plan view illustrating pixels according to the modified example. In the modified example, the line width of the detection drive line 12 is adjusted to be thinner than that of the drive lines 10 and 11. More specifically, in a region neighboring a pixel row including the detection pixel 101c (within a range of the pixel matrix), the detection drive line 12 is uniformly formed to have a thinner line width than the line width of the drive lines 10 and 11. With such a configuration, it is possible to widen the opening portion 112b of the second image capturing pixel 101b by an amount of reduction in the line width of the detection drive line 12. In addition, by reducing a difference in shape between the opening portions of the first image capturing pixel 101a and the second image capturing pixel 101b, it is possible to make the distance 132aa between the centroids and the distance 132ab between the centroids substantially equal, and to prevent moire. In view of the contrast of moire, it is desirable that a difference between the distances 132aa and 132ab between the centroids fall within 10% of the distance 132aa between the centroids.

When the line width of the detection drive line 12 is made thinner, wiring resistance becomes higher, and it is considered that supply capacity of drive signals to switch elements may be affected. Nevertheless, the number of detection pixels connected to the drive line 12 is smaller than the number of image capturing pixels connected to the drive lines 10 and 11. In other words, the number of switch elements connected to wiring lines is small, and the total capacity is also small. Accordingly, it is possible to ensure sufficient driving capability even when the line width is made thinner. It is desirable that the line width of the drive line 12 be 65% or more of the line width of the drive lines 10 and 11.

Similarly, the number of image capturing pixels connected to the drive line 11 is smaller than the number of image capturing pixels connected to the drive line 10. In other words, the number of switch elements connected to wiring lines is small, and the total capacity is also small. For this reason, within the range of the pixel matrix, the line width of the drive line 11 may be made thinner than the line width of the drive line 10. In addition, areas of the opening portions of the second image capturing pixel 101b and the detection pixel 101c may be widen by an amount of reduction in the line width of the drive line 10.

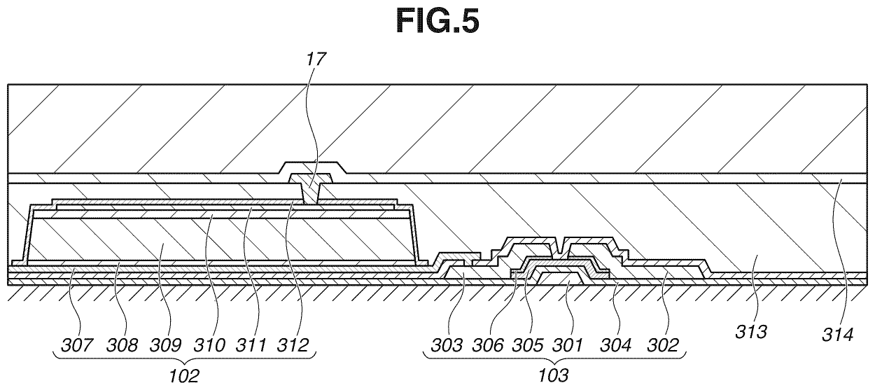

FIG. 5 is a cross-sectional view taken along line A-A′ in FIG. 4. The conversion element 102 is arranged in a left portion, and the switch element 103 is arranged in a right portion. The switch element 103 includes a gate electrode 301, a source electrode 302, a drain electrode 303, an insulation layer 304, a first semiconductor layer 305, and a first impurity semiconductor layer 306. The conversion element 102 includes a lower electrode 307, a second impurity semiconductor layer 308, a second semiconductor layer 309, a third impurity semiconductor layer 310, an upper electrode 311, and a protective layer 312.

The drain electrode 303 is connected to the lower electrode 307 by a contact. The upper electrode 311 is connected to the bias line 17 by a contact. The gate electrode 301 of the switch element 103 constitutes a part of the drive line 10, and the source electrode 302 constitutes a part of the signal line 20. By supplying a drive signal to the drive line 10 and turning on the switch element 103, the charge accumulated in the conversion element 102 is transferred to the signal line 20 as an electrical signal. A light shielding layer (light shielding portion) made of metal or the like may be formed on the switch element 103. The light shielding layer is formed of the same metal layer as the bias line 17, and the light shielding layer and the bias line 17 may be connected. By shielding the switch element 103, it is possible to prevent a charge that becomes noise from being generated due to irradiation of the semiconductor layer of the switch element 103 with light. It is also possible to prevent the charge accumulated in the conversion element 102 from leaking.

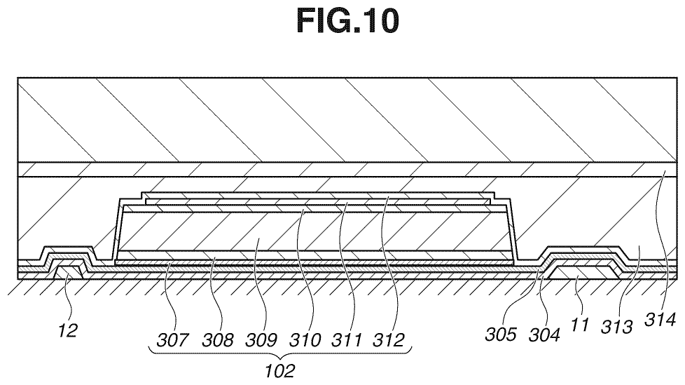

FIG. 10 is a cross-sectional view taken along line B-B′ in FIG. 4. In FIG. 10, the drive line 12 is arranged in a left portion, the drive line 11 is arranged in a right portion, and the conversion element 102 is arranged at the center. As can be seen in FIG. 10, the drive line 12 and the drive line 11 are arranged in the same layer. In addition, the drive line 10, which is not illustrated, is arranged in the same layer on the left side of the drive line 12. In this manner, the drive lines 10, 11, and 12 are subject to restriction in arrangement. In addition, the width of the drive line 12 affects the width of the conversion element 102. For this reason, in this modified example, a design has been made such that the width of the drive line 12 is thinner.

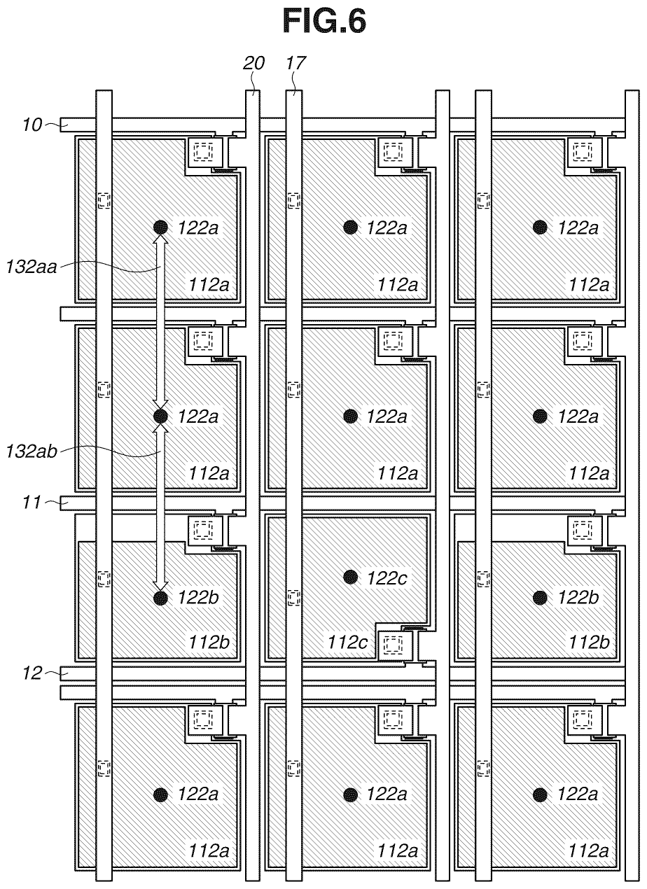

Next, a second exemplary embodiment will be described. The second exemplary embodiment differs from the first exemplary embodiment in that the centroid position of an opening portion is adjusted by varying the shape of a conversion element of the second image capturing pixel 101b. FIG. 6 is a plan view illustrating a pixel matrix according to the second exemplary embodiment.

As described above, by the detection drive line 12 being arranged, as compared with the first image capturing pixel 101a, the centroid position of the second image capturing pixel 101b is shifted upward. In view of the foregoing, in the present exemplary embodiment, the centroid position is adjusted downward by varying the shape of an opening portion by removing an upper portion of the conversion element of the second image capturing pixel 101b. With such a configuration, it is possible to make the distance 132aa between the centroids and the distance 132ab between the centroids substantially equal in the signal line direction, and to prevent moire.

On the other hand, the structure illustrated in FIG. 6 is a structure in which a distance between the opening portion 112a of the first image capturing pixel 101a and the opening portion 112b of the second image capturing pixel 101b that neighbor vertically increases. When the distance increases, the contrast of moire might become high due to the distance. For this reason, it is desirable that the maximum value of the distance (gap) in the signal line direction between the opening portions of the first and second image capturing pixels be within 50% of the distance 132aa between centroids in the signal line direction.

In the present exemplary embodiment, only the shape of the conversion element is varied without varying the shape of the lower electrode as compared with FIG. 3, but the shape of the lower electrode may be varied in accordance with the shape of the conversion element.

Next, a third exemplary embodiment will be described. The third exemplary embodiment differs from the first exemplary embodiment in that the centroid position of an opening portion is adjusted by changing a shielded region by varying the shape of the bias line of the second image capturing pixel 101b.

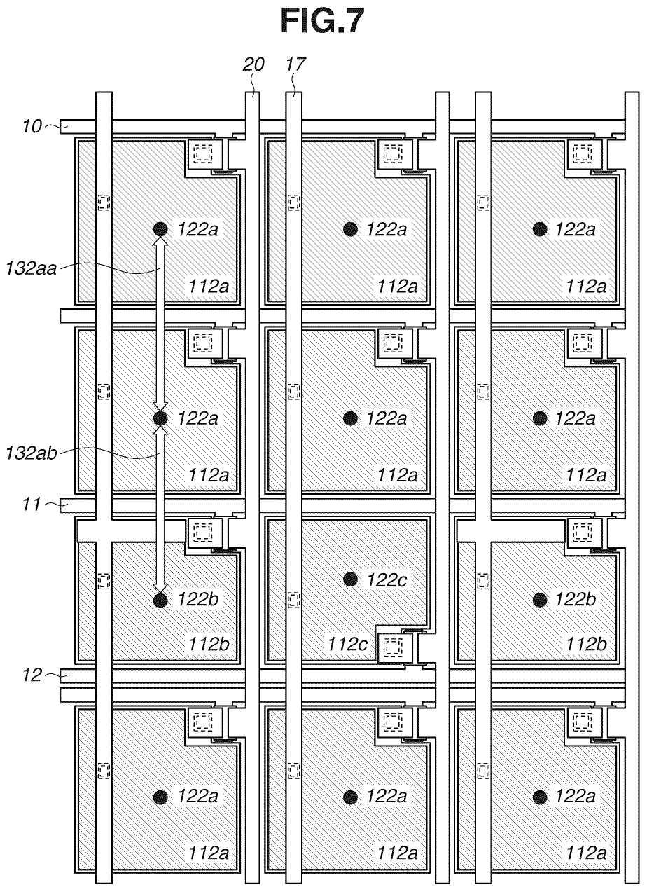

FIG. 7 is a plan view illustrating a pixel matrix according to the third exemplary embodiment. As illustrated in FIG. 7, by adjusting the centroid position by varying the shape of the opening portion by shielding an upper portion of the conversion element with the bias line, it is possible to make the distance 132aa between the centroids and the distance 132ab between the centroids substantially equal in the signal line direction, and to prevent moire. The adjustment of the centroid position of the second image capturing pixel 101b and the distance in the signal line direction between the opening portions of the first and second image capturing pixels are based on the same concept as that of the second exemplary embodiment in FIG. 6.

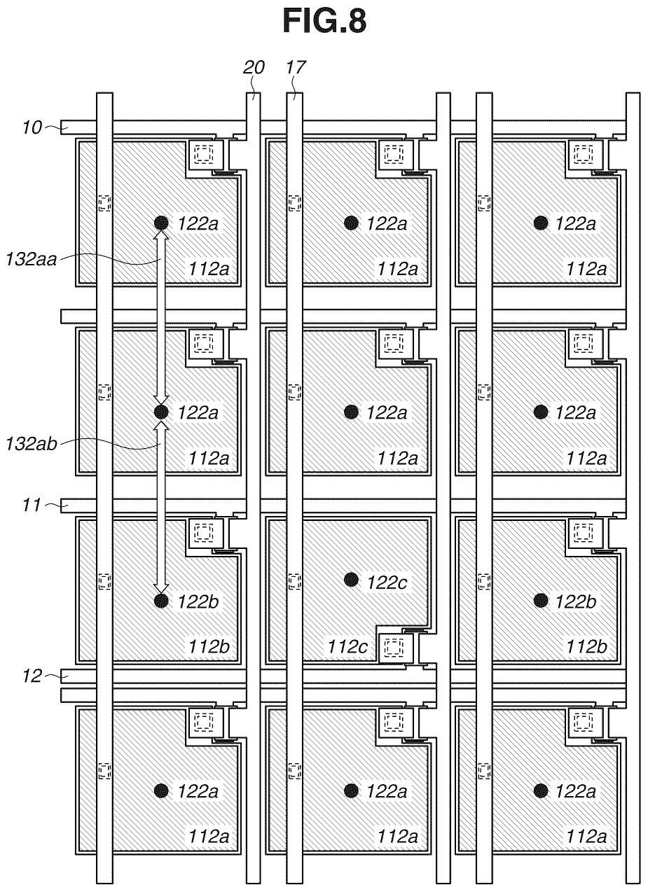

Next, a fourth exemplary embodiment will be described. The fourth exemplary embodiment differs from the first exemplary embodiment in that the centroid position is adjusted by varying the shape of a conversion element of the first image capturing pixel 101a. FIG. 8 is a plan view illustrating a pixel matrix according to the fourth exemplary embodiment. Due to arrangement of the detection drive line 12, compared with the centroid position of the first image capturing pixel 101a, the centroid position of the second image capturing pixel 101b is shifted upward. By adjusting the centroid position upward by varying the shape of the opening portion by removing a lower portion of the conversion element of the first image capturing pixel 101a, it is possible to make the distance 132aa between the centroids and the distance 132ab between the centroids substantially equal in the signal line direction, and to prevent moire. In addition, the distance 132aa between the centroids and the distance 132ab between the centroids may be made equal by making the shape of the conversion element of the first image capturing pixel 101a the same as the shape of the conversion element of the second image capturing pixel 101b. Further, by making the shape of the conversion element of the first image capturing pixel 101a small, it is possible to widen a region where the drive line can be arranged. In other words, it becomes possible to vary the position of the drive line. For this reason, in a row near the row in which the second image capturing pixel 101b is arranged, the position of the drive line of the first image capturing pixel 101a may be varied. The distance 132aa between centroids and the distance 132ab between the centroids may be made substantially equal by varying the shape of the conversion element of the first image capturing pixel 101a. A distance in the signal line direction between the opening portions of the first and second image capturing pixels is based on the same concept as that of the second exemplary embodiment in FIG. 6. In the present exemplary embodiment, the example in which the shape of the lower electrode is also varied in accordance with the shape of the conversion element of the first image capturing pixel 101a has been described, but the distance 132aa between the centroids and the distance 132ab between the centroids may be made substantially equal by making only the shape of the conversion element different from that in FIG. 3 and making the shape of the lower electrode similar to that in FIG. 3. In addition, as illustrated in FIG. 7, the distance 132aa between the centroids and the distance 132ab between the centroids may be made substantially equal by varying the shape of the opening portion with a shielded region of the bias line of the first image capturing pixel 101a.

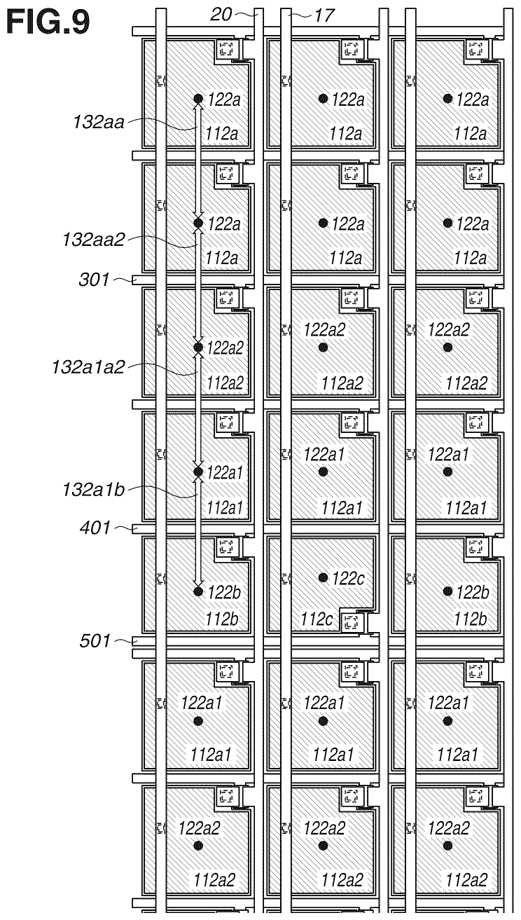

Next, a fifth exemplary embodiment will be described. The fifth exemplary embodiment differs from the first exemplary embodiment in that distances between centroids are made substantially equal using a row in which a detection pixel and the second image capturing pixel 101b are arranged, and a plurality of nearby rows in which the first image capturing pixels 101a are arranged. FIG. 9 is a plan view illustrating a pixel matrix according to the fifth exemplary embodiment. FIG. 9 illustrates a configuration in which distances 132a1b, 132a1a2, 132aa2, and 132aa between the centroids are made substantially equal across a plurality of rows. In other words, a difference between the distances 132a1b and 132a1a2 between the centroids falls within 10% of the distance 132a1b between the centroids. A difference between the distances 132a1a2 and 132aa2 between the centroids falls within 10% of the distance 132a1a2 between the centroids. A difference between the distances 132aa2 and 132aa between the centroids falls within 10% of the distance 132aa2 between centroids. In addition, it is desirable that the distance 132a1b between the centroids be shorter than the distance 132a1a2 between the centroids. It is desirable that the distance 132a1a2 between the centroids be shorter than the distance 132aa2 between the centroids. It is desirable that the distance 132aa2 between the centroids be shorter than the distance 132aa between the centroids. By adjusting the centroid position of the second image capturing pixel 101b, which has a different centroid position from that of the first image capturing pixel 101a, by also adjusting the centroid positions of a plurality of nearby first image capturing pixels 101a it is possible to distribute the influence of different distances between the centroids across a plurality rows. One or more of the methods described in the first exemplary embodiment in FIG. 4, in the second exemplary embodiment in FIG. 6, in the third exemplary embodiment in FIG. 7, and in the fourth exemplary embodiment in FIG. 8 may be used to adjust the distances between the centroids. In other words, it is possible to appropriately change a centroid position by changing the size or the shape of the light shielding portion (bias line 17), or the size or the shape of the conversion element 102a, 102b, or 102c.

Meanwhile, in a radiation imaging apparatus in which pixels for image capturing and pixels for automatic exposure control (AEC) are connected to different drive lines, the case of simultaneously driving pixels arranged in a plurality of pixel rows, among the pixels for image capturing, such as binning driving, is considered. Hereinafter, an operation to be performed in the case of simultaneously driving a plurality of pixel rows will be described. In the following description, pixels to be used to acquire radiographic images, such as the above-described first image capturing pixels 101a and second image capturing pixels 101b, will be sometimes simply referred to as image capturing pixels 101a. In a case where no distinction is made between the image capturing pixels 101a and the detection pixels 101c, these pixels will be sometimes simply referred to as pixels 101. Regarding the drive line 10 and the drive line 11, drive lines to which the image capturing pixels 101a are connected will be sometimes collectively referred to as drive lines 10.

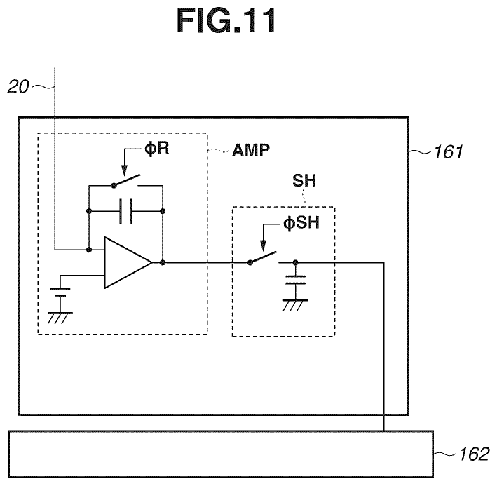

FIG. 11 illustrates a configuration example of a detailed circuit of the amplifying unit 161. The amplifying unit 161 can include a differential amplifier circuit AMP and a sample and hold circuit SH. The differential amplifier circuit AMP amplifies a signal appearing on the signal line 20, and outputs the amplified signal. The control unit 180 can reset the potential of the signal line 20 by supplying a control signal R to a switch element of the differential amplifier circuit AMP. The output of the differential amplifier circuit AMP can be held by the sample and hold circuit SH. By supplying a control signal ϕSH to a switch element of the sample and hold circuit SH, the control unit 180 causes the sample and hold circuit SH to hold a signal. The signal held by the sample and hold circuit SH is read out by the multiplexer 162.

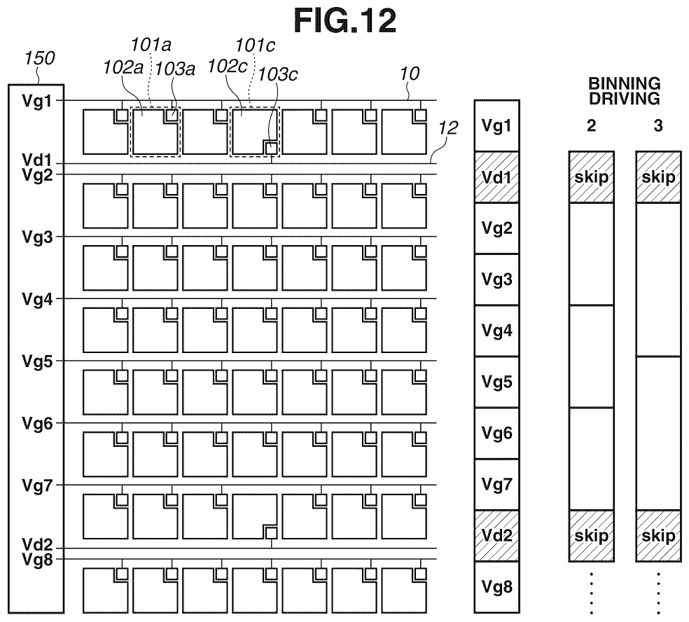

Subsequently, an operation of the radiation imaging apparatus 100 according to the present exemplary embodiment will be described with reference to FIGS. 12 to 14. In the radiation imaging apparatus 100 according to the present exemplary embodiment, the drive circuit 150 has an operation mode in which a predetermined number (two or more) of drive lines 10 among a plurality of drive lines 10 connected to the image capturing pixels 101a are driven simultaneously. For example, after radiation emission, in binning driving of reading out signals from the image capturing pixels 101a to acquire a binning image, or in automatic detection driving for detecting a start of radiation emission, the predetermined number (two or more) of the drive lines 10 among the plurality of drive lines 10 are simultaneously driven. At this time, in some cases, the drive line 12 connected to the detection pixel 101c is not used in the binning driving or the automatic detection driving because the drive line 12 is used for detection of an integrated dose, for example. Accordingly, in the binning driving or automatic detection driving, in a case where signals are read out by driving the drive line 12, image quality degradation of binning pixels and degradation of detection sensitivity to a radiation emission start may occur. In view of the foregoing, in the present exemplary embodiment, a plurality of drive lines 12 arrayed in the radiation detection sensor IR includes two drive lines 12 between which no other drive line 12 is arranged. In this case, the number of drive lines 10 arranged between the two drive lines 12 between which no other drive line 12 is arranged, among a plurality of drive lines 10, is a positive integer multiple of the number of drive lines 10 simultaneously driven in the binning driving or the automatic detection driving. Furthermore, the drive circuit 150 does not have to drive a plurality of drive lines 12 in operation modes in which a predetermined number of drive lines 10 are simultaneously driven such as the binning driving and the automatic detection driving. With this configuration, in these operation modes, it becomes possible to suppress an influence to be exerted in the case of reading out the drive line 12 connected to the image capturing pixel 101a, and prevent degradation of image quality and detection accuracy.

FIG. 12 is a diagram illustrating an arrangement example of the drive line 10 and the drive line 12. For example, the drive circuit 150 may have an operation mode of simultaneously operating two drive lines 10 of the plurality of drive lines 10, and another operation mode of simultaneously driving three drive lines 10 different from the two drive lines 10. In this case, the number of drive lines 10 arranged between the two drive lines 12 between which no other drive line 12 is arranged, among the plurality of drive lines 10 may be a common multiple of 2 and 3. In the configuration illustrated in FIG. 12, six drive lines 10 are arranged between the two drive lines 12. Nevertheless, in an operation mode of simultaneously driving two or more drive lines 10, four or more drive lines 10 may be simultaneously driven instead of two drive lines 10 or three drive lines 10. In addition, the drive circuit 150 operating in accordance with the control unit 180 may have three or more types of operation modes. It can also be said that the radiation imaging apparatus 100 has three or more types of operation modes. In these operation modes, the drive circuit 150 may simultaneously drive a predetermined number of consecutively-arranged drive lines 10 among the plurality of drive lines 10, as described below.

In the following description, signals to be applied to the drive lines 10 that drive the image capturing pixels 101a are denoted by Vg1 to Vgn, and signals to be applied to the drive lines 12 that drive the detection pixels 101c are denoted by Vd1 and Vd2. No other drive line 12 is arranged between the drive line 12 to which the signal Vd1 is supplied, and the drive line 12 to which the signal Vd2 is supplied. For example, in the drive lines 10 to which signals Vg2 to Vg7 are supplied from the drive circuit 150, when binning driving of simultaneously driving two drive lines 10 is performed, drive signals (high level) are simultaneously supplied to the signals Vg2 and Vg3, and corresponding drive lines 10 are simultaneously driven. Accordingly, signals are simultaneously read out from the image capturing pixels 101a connected to the drive lines 10 to which the signals Vg2 and Vg3 are supplied. The drive lines 10 to which the signals Vg2 and Vg3 are supplied can be the drive lines 10 consecutively-arranged in the pixel column direction as illustrated in FIG. 12. Similarly, drive signals are simultaneously supplied to the signals Vg4 and Vg5, and corresponding drive lines 10 are simultaneously driven. Drive signals are simultaneously supplied to the signals Vg6 and Vg7, and corresponding drive lines 10 are simultaneously driven. In addition, for example, in binning driving of simultaneously driving three drive lines 10, drive signals are simultaneously supplied to the signals Vg2, Vg3, and Vg4, and corresponding drive lines 10 are simultaneously driven. Drive signals are simultaneously supplied to the signals Vg5, Vg6, and Vg7, and corresponding drive lines 10 are simultaneously driven. In this manner, by arranging the drive lines 10 such that the number of drive lines 10 arranged between the two drive lines 12 becomes a positive integer multiple of the number of drive lines 10 to be simultaneously driven, and skipping the drive line 12, it is possible to suppress influence to be exerted in the case of driving the drive lines 12 in the binning driving or automatic detection driving.

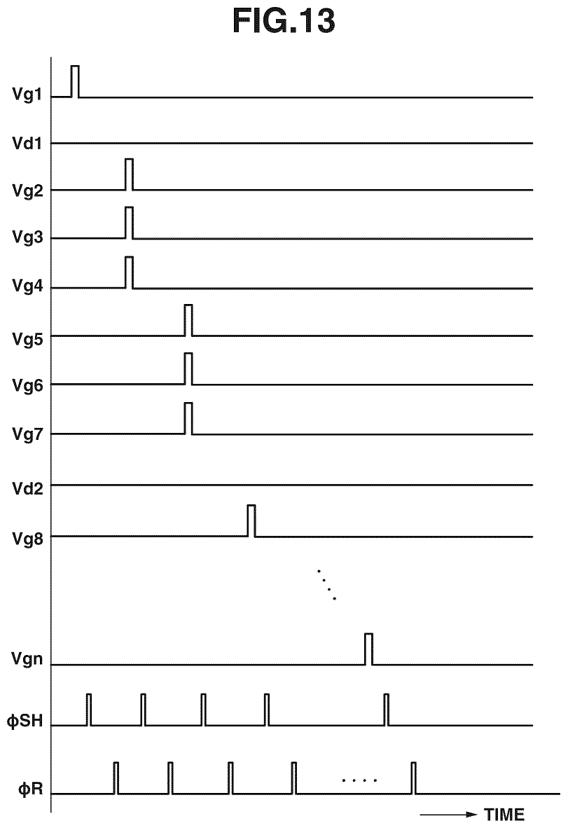

FIG. 13 illustrates an operation example in the binning driving of simultaneously driving three drive lines 10. The binning driving is driving of simultaneously reading out signals from the pixels 101 arrayed in a plurality of pixel rows, to acquire a radiographic image. In the binning driving, drive signals are simultaneously supplied to the drive lines 10 to be simultaneously driven. After the drive signals are supplied, the drive circuit 150 supplies the control signal QR to the switch element of the sample and hold circuit SH of the amplifying unit 161, and performs a reset operation of the potential of the signal line 20. The drive circuit 150 sequentially repeats these operations in the binning driving.

When the drive lines 10 are driven in order during the binning driving, three drive lines 10 to which the signals Vg2, Vg3, and Vg4 are supplied are simultaneously driven without driving the drive line 12 to which the signal Vd1 is supplied. Accordingly, signals are read out from the image capturing pixels 101a connected to the three drive lines 10 to which the signals Vg2, Vg3, and Vg4 are supplied. Subsequently, three drive lines 10 to which the signals Vg5, Vg6, and Vg7 are supplied are simultaneously driven. Accordingly, signals are read out from the image capturing pixels 101a connected to the three drive lines 10 to which the signals Vg5, Vg6, and Vg7 are supplied. Subsequently, the drive circuit 150 similarly drives each drive line 10 until the drive line 10 to which the signal Vgn is supplied is driven, without driving the drive line 12 to which the signal Vd2 is supplied. As described above, by executing the binning driving without driving the drive line 12, it is possible to prevent image quality degradation of radiographic images caused by driving the drive line 12.

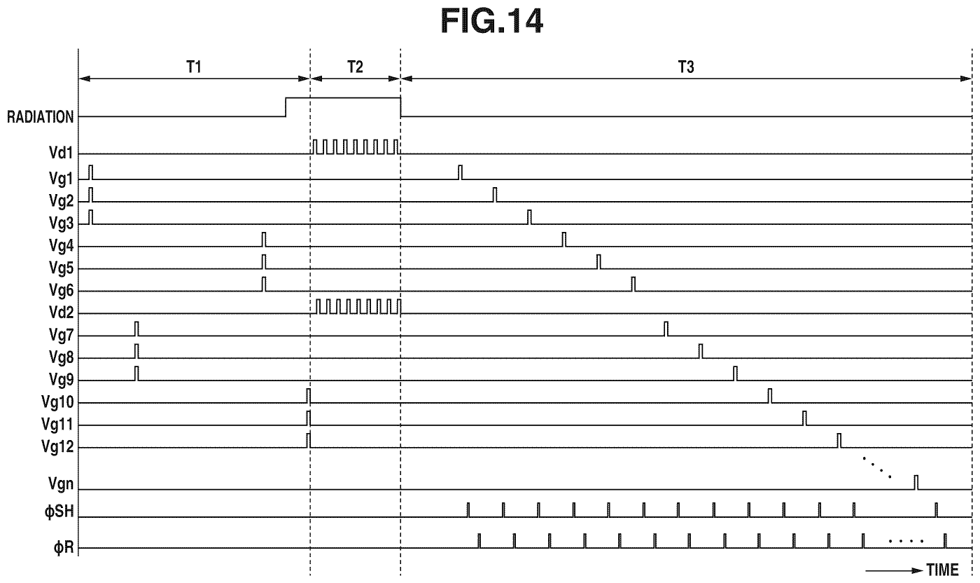

FIG. 14 illustrates an operation example in the automatic detection driving of simultaneously driving the three drive lines 10 and detecting a radiation emission start. In the operation example illustrated in FIG. 14, the drive lines 10 to which the signals Vg1 to Vg3 are supplied are driven, and subsequently, the drive lines 10 to which the signals Vg7 to Vg9 are supplied are driven. Furthermore, the drive lines 10 to which the signals Vg4 to Vg6 are supplied are driven, and subsequently, the drive lines 10 to which signals Vg10 to Vg12 are supplied are driven. In this manner, FIG. 14 illustrates an example of alternately reading out signals from the image capturing pixels 101a connected to a group of drive lines including the three drive lines 10. Alternately reading out signals means scanning the radiation detection sensor IR so as to sequentially read out signals from the image capturing pixels 101a connected to the drive lines 10 to which the signals Vg1 to Vg3 are supplied, and the image capturing pixels 101a connected to the drive lines 10 to which the signals Vg7 to Vg9 are supplied, and then, scanning the radiation detection sensor IR so as to sequentially read out signals from the image capturing pixels 101a connected to the drive lines 10 to which the signals Vg4 to Vg6 are supplied, and the image capturing pixels 101a connected to the drive lines 10 to which the signals Vg10 to Vg12 are supplied. While not illustrated, the drive lines 10 to which signals Vg13 to Vgn are supplied are also driven during a period from the time when the drive signals are supplied to the signals Vg1 to Vg3 to the time when the drive signals are supplied to the signals Vg7 to Vg9, during a period from the time when the drive signals are supplied to the signals Vg7 to Vg9 to the time when the drive signals are supplied to the signals Vg4 to Vg6, or during a period from when the drive signals are supplied to the signals Vg4 to Vg6 to when the drive signals are supplied to the signals Vg10 to Vg12.

An order in which the drive signals are supplied to the drive lines 10 is not limited to the order in the operation example illustrated in FIG. 14. For example, the drive circuit 150 supplies the drive signals to the signals Vg1 to Vg3, and subsequently supplies the drive signals to the signals Vg4 to Vg6. Furthermore, the drive circuit 150 supplies the drive signals to the signals Vg7 to Vg9, and subsequently supplies the drive signals to the signals Vg10 to Vg12. In this case, for example, signals are sequentially read out from the image capturing pixels 101a arranged in a predetermined number of pixel rows at one end of the radiation detection sensor IR, and from the image capturing pixels 101a arranged in a predetermined number of pixel rows at the other end.

In FIG. 14, a period T1 is a period of waiting for a radiation emission start. Specifically, a period from the time when the radiation imaging apparatus 100 is powered on, a reset operation of a pixel 101 is performed, and a state in which capturing of radiographic images is enabled is achieved, to the time when the exposure switch of the radiation source 501 is operated and radiation emission is detected corresponds to the period T1. As described above, by the drive circuit 150 simultaneously driving the three drive lines 10 in a predetermined order, signals are alternately read out from the image capturing pixels 101a connected to the group of drive lines including the three drive lines 10. Drive signals are simultaneously supplied to the three drive lines 10 to be simultaneously driven. In the period T1, the signals Vd1 and Vd2 remain at a low level, and the drive lines 12 are not driven. When radiation emission is started, charge is accumulated in the image capturing pixel 101a, and when the accumulated charge is read out, a bias voltage varies due to movement of the charge. For this reason, for example, the signal processing unit 170 detects a radiation emission start by monitoring a variation in the bias voltage caused by the readout from the image capturing pixel 101a. When the radiation emission start is detected, the period transitions to a period T2.

The period T2 is a period during which radiation is emitted, and an accumulation operation for acquiring a radiographic image is performed in the image capturing pixel 101a. In the period T2, by the signals Vg1 to Vgn to be applied to the drive lines 10 remaining at the low level, charge corresponding to emitted radiation is accumulated in the conversion element 102a of the image capturing pixel 101a. In addition, as illustrated in FIG. 14, in the period T2, the drive circuit 150 may drive a plurality of drive lines 12 in accordance with the control unit 180. Specifically, by the drive circuit 150 supplying drive signals (high level) to the signals Vd1 and Vd2, signals are read out from the detection pixel 101c. The signal processing unit 170 acquires an irradiation amount and an integrated dose of incident radiation based on the signals output from the detection pixel 101c. In accordance with irradiation information such as the irradiation amount and the integrated dose of incident radiation that has been acquired by the signal processing unit 170, the control unit 180 transmits an end request signal to the radiation source interface 502 via the communication interface 503. Upon receiving the end request signal, the radiation source interface 502 causes the radiation source 501 to end radiation emission. The automatic exposure control (AEC) is thereby implemented. When the radiation emission ends, the period transitions to a period T3.

The period T3 is a period of reading out signals accumulated in the image capturing pixel 101a in accordance with the incidence of radiation after the radiation emission ends. In the period T3, for example, unlike the period T1, the drive circuit 150 sequentially supplies drive signals to the image capturing pixels 101a to which the respective signals Vg1 to Vgn are supplied, one pixel row by one pixel row. Accordingly, signals accumulated in the image capturing pixels 101a are sequentially read out by the readout circuit 160 for each pixel row. In this manner, the drive circuit 150 may change the number of drive lines 10 to be simultaneously driven among the plurality of drive lines 10 between the time of detecting a radiation emission start and the time of reading out signals from the plurality of image capturing pixels 101a after radiation emission. In the period T3, the signals Vd1 and Vd2 remain at the low level, and the drive line 12 is not driven.

The case of driving the drive line 12 and reading out signals also from the detection pixels 101c when the automatic detection driving of detecting a radiation emission start is performed will be considered. In this case, the number of detection pixels 101c arranged in one pixel row is smaller than the number of image capturing pixels 101a arranged in one pixel row. For this reason, a variation in bias voltage caused by reading out the charge accumulated in the pixel 101 by radiation emission becomes smaller, and detection sensitivity to a radiation emission start may deteriorate. In view of the foregoing, as described above, by arranging the drive lines 10 so that the number of drive lines 10 arranged between the drive lines 12 becomes a positive integer multiple of the number of drive lines 10 to be simultaneously driven and avoiding driving of the drive lines 12 in performing the automatic detection driving, the automatic detection driving is executed. With this configuration, it is possible to prevent degradation of detection accuracy of a radiation emission start.

While the present disclosure has been described with reference to the exemplary embodiments, the present disclosure is not limited to the above-described exemplary embodiments. The disclosure includes disclosures modified within the scope not departing from the gist of the disclosure and disclosures equivalent to the present disclosure. For example, not all combinations of the features described in the above exemplary embodiments are necessarily essential to the solution of the present disclosure. A part of the features may be replaced with another feature or deleted within a range in which the effect of the present disclosure is obtained. The dimensions, materials, shapes, relative positions of the components, and the like described in the above exemplary embodiments are examples, and can be changed as appropriate according to conditions. The above-described exemplary embodiments and modified examples can be combined as appropriate without departing from the gist of the present disclosure.

### Other Embodiments

Embodiment(s) of the present disclosure can also be realized by a computer of a system or apparatus that reads out and executes computer executable instructions (e.g., one or more programs) recorded on a storage medium (which may also be referred to more fully as a ‘non-transitory computer-readable storage medium’) to perform the functions of one or more of the above-described embodiment(s) and/or that includes one or more circuits (e.g., application specific integrated circuit (ASIC)) for performing the functions of one or more of the above-described embodiment(s), and by a method performed by the computer of the system or apparatus by, for example, reading out and executing the computer executable instructions from the storage medium to perform the functions of one or more of the above-described embodiment(s) and/or controlling the one or more circuits to perform the functions of one or more of the above-described embodiment(s). The computer may comprise one or more processors (e.g., central processing unit (CPU), micro processing unit (MPU)) and may include a network of separate computers or separate processors to read out and execute the computer executable instructions. The computer executable instructions may be provided to the computer, for example, from a network or the storage medium. The storage medium may include, for example, one or more of a hard disk, a random-access memory (RAM), a read only memory (ROM), a storage of distributed computing systems, an optical disk (such as a compact disc (CD), digital versatile disc (DVD), or Blu-ray Disc (BD) TM), a flash memory device, a memory card, and the like.

### (Additional Statements)

This specification includes the following disclosure.

### [Additional Statement 1]

A radiation detection sensor comprising:
a pixel matrix in which a plurality of pixels, each including a conversion element that converts radiation or light into a charge, and a switch element, is arranged in a matrix, the pixel matrix including a plurality of image capturing pixels to be used for acquisition of a radiographic image, and a plurality of detection pixels to be used for detection of a dose of radiation;
a first drive line for driving a switch element of the image capturing pixel included in a first row of the pixel matrix; and
a second drive line for driving a switch element of the detection pixel included in the first row of the pixel matrix,
in which a second row different from the first row neither includes the detection pixel nor the second drive line, an average area of opening portions of a plurality of image capturing pixels with a first shape being the image capturing pixels included in the first row, is a first average area, an average area of opening portions of image capturing pixels with a second shape being the image capturing pixels included in the second row, is a second average area, the first average area is smaller than the second average area, and an error of an area of each opening portion of the image capturing pixel with the first shape being included in the first row falls within 1% of the first average area.

### [Additional Statement 2]

The radiation detection sensor according to Additional Statement 1,
in which the first row and the second row are neighboring rows,
in which the pixel matrix includes a third row neighboring the second row on an opposite side of the first row, the third row including an image capturing pixel with the second shape,
in which the pixel matrix includes a first image capturing pixel included in the first row, a second image capturing pixel included in the second row and neighboring the first image capturing pixel, and a third image capturing pixel included in the third row and neighboring the second image capturing pixel, and
in which a distance between centroids of the first image capturing pixel and the second image capturing pixel is substantially equal to a distance between centroids of the second image capturing pixel and the third image capturing pixel.

### [Additional Statement 3]

The radiation detection sensor according to Additional Statement 2, in which a difference between the distance between the centroids of the first image capturing pixel and the second image capturing pixel and the distance between the centroids of the second image capturing pixel and the third image capturing pixel falls within 10%.

### [Additional Statement 4]

The radiation detection sensor according to Additional Statement 2 or 3, in which a size of a gap generated between the first image capturing pixel and the second image capturing pixel falls within 50% of the distance between the centroids of the first image capturing pixel and the second image capturing pixel.

### [Additional Statement 5]

The radiation detection sensor according to any one of Additional Statements 1 to 4, in which a line width of the second drive line is thinner than a line width of the first drive line.

### [Additional Statement 6]

The radiation detection sensor according to any one of Additional Statements 1 to 5, in which a conversion element of the image capturing pixel with the first shape and a conversion element of the image capturing pixel with the second shape differ in shape.

### [Additional Statement 7]

The radiation detection sensor according to any one of Additional Statements 1 to 6, in which an opening portion of the image capturing pixel with the first shape is a region of the conversion element of the image capturing pixel with the first shape that excludes a region shielded by a light shielding portion.

### [Additional Statement 8]

The radiation detection sensor according to any one of Additional Statements 1 to 7, in which an opening portion of the image capturing pixel with the second shape is a region of the conversion element of the image capturing pixel with the second shape that excludes a region shielded by a light shielding portion.

### [Additional Statement 9]

The radiation detection sensor according to any one of Additional Statements 1 to 8, in which the first drive line is provided on an opposite side of the second drive line across the image capturing pixel included in the first row and sandwiched therebetween.

### [Additional Statement 10]

The radiation detection sensor according to any one of Additional Statements 1 to 9,
in which a third drive line connecting to the image capturing pixel with the second shape included in the second row is included, and
in which a line width of the third drive line is thinner than a line width of the first drive line.

### [Additional Statement 11]

A radiation imaging apparatus that acquires a radiographic image based on radiation, the radiation imaging apparatus comprising:
a pixel matrix in which a plurality of pixels, each including a conversion element that converts radiation or light into a charge, and a switch element, is arranged in a matrix, the pixel matrix including an image capturing pixel to be used for acquisition of a radiographic image, and a detection pixel to be used for detection of a dose of radiation;
a first drive line for driving a switch element of the image capturing pixel included in a first row of the pixel matrix; and
a second drive line for driving a switch element of the detection pixel included in the first row of the pixel matrix,
in which a second row different from the first row neither includes the detection pixel nor the second drive line, an average area of opening portions of a plurality of image capturing pixels with a first shape being image capturing pixels included in the first row, is a first average area, an average area of an opening portion of image capturing pixels with a second shape being the image capturing pixels included in the second row, is a second average area, the first average area is smaller than the second average area, and an error of an area of each opening portion of the image capturing pixel with the first shape being included on the first row falls within 1% of the first average area.

### [Additional Statement 12]

A manufacturing method of a radiation detection sensor, the manufacturing method comprising:
providing a pixel matrix in which a plurality of pixels, each including a conversion element that converts radiation or light into a charge, and a switch element, is arranged in a matrix, the pixel matrix including a plurality of image capturing pixels to be used for acquisition of a radiographic image, and a plurality of detection pixels to be used for detection of a dose of radiation;
providing a first drive line for driving a switch element of the image capturing pixel included in a first row of the pixel matrix; and
providing a second drive line for driving a switch element of the detection pixel included in the first row of the pixel matrix,
in which a second row different from the first row neither includes the detection pixel nor the second drive line, an average area of opening portions of a plurality of image capturing pixels with a first shape being the image capturing pixels included in the first row, is a first average area, an average area of opening portions of image capturing pixels with a second shape being the image capturing pixels included in the second row, is a second average area, the first average area is smaller than the second average area, and an error of an area of each opening portion of the image capturing pixel with the first shape being included in the first row falls within 1% of the first average area.

### [Additional Statement 13]

A radiation detection sensor comprising:
a pixel matrix in which a plurality of pixels each including a conversion element that converts radiation or light into a charge, and a switch element, is arranged in a matrix, the pixel matrix including an image capturing pixel to be used for acquisition of a radiographic image, and a detection pixel to be used for detection of a dose of radiation;
a first drive line for driving a switch element of the image capturing pixel included in a predetermined row of the pixel matrix; and
a second drive line for driving a switch element of the detection pixel included in a predetermined row of the pixel matrix,
in which a line width of the second drive line is thinner than a line width of the first drive line.

### [Additional Statement 14]

The radiation detection sensor according to Additional Statement 13, in which the first drive line is provided on an opposite side of the second drive line across the image capturing pixel included in the first row and sandwiched therebetween.

### [Additional Statement 15]

The radiation detection sensor according to Additional Statement 13 or 14,
in which a third drive line connecting to the image capturing pixel with the second shape included in a row different from the predetermined row is included, and
in which a line width of the third drive line is thinner than a line width of the first drive line.

### [Additional Statement 16]

A radiation imaging apparatus that acquires a radiographic image based on radiation, the radiation imaging apparatus comprising:
a pixel matrix in which a plurality of pixels, each including a conversion element that converts radiation or light into a charge, and a switch element, is arranged in a matrix, the pixel matrix including an image capturing pixel to be used for acquisition of a radiographic image, and a detection pixel to be used for detection of a dose of radiation;
a first drive line for driving a switch element of the image capturing pixel included in a predetermined row of the pixel matrix; and
a second drive line for driving a switch element of the detection pixel included in the predetermined row of the pixel matrix,
in which a line width of the second drive line is thinner than a line width of the first drive line.

### [Additional Statement 17]

A manufacturing method of a radiation detection sensor, the manufacturing method comprising:
providing a pixel matrix in which a plurality of pixels, each including a conversion element that converts radiation or light into a charge, and a switch element, is arranged in a matrix, the pixel matrix including an image capturing pixel to be used for acquisition of a radiographic image, and a detection pixel to be used for detection of a dose of radiation;
providing a first drive line for driving a switch element of the image capturing pixel included on a predetermined row of the pixel matrix; and
providing a second drive line for driving a switch element of the detection pixel included in a predetermined row of the pixel matrix,
in which a line width of the second drive line is thinner than a line width of the first drive line.

### [Additional Statement 18]

A radiation detection sensor comprising:
a pixel matrix in which a plurality of pixels, each including a conversion element that converts radiation or light into a charge, and a switch element, is arranged in a matrix, the pixel matrix including a plurality of image capturing pixels to be used for acquisition of a radiographic image, and a plurality of detection pixels to be used for detection of a dose of radiation;
a first drive line for driving a switch element of the image capturing pixel included in a first row of the pixel matrix; and
a second drive line for driving a switch element of the detection pixel included in the first row of the pixel matrix,
in which a second row neighboring the first row and a third row neighboring the second row neither includes the detection pixel nor the second drive line,
in which a first image capturing pixel being an image capturing pixel with a first shape is provided in a predetermined column of the first row,
in which a second image capturing pixel being an image capturing pixel with a second shape is provided in a predetermined column of the second row,
in which a third image capturing pixel being an image capturing pixel with the second shape is provided in a predetermined column of the third row, and
in which a distance between centroids between a centroid of an opening portion of the first image capturing pixel and a centroid of an opening portion of the second image capturing pixel is substantially equal to a distance between centroids between the centroid of the opening portion of the second image capturing pixel and a centroid of an opening portion of the third image capturing pixel.

### [Additional Statement 19]

The radiation detection sensor according to Additional Statement 18, in which a difference between a first distance between centroids between the centroid of the opening portion of the first image capturing pixel and the centroid of the opening portion of the second image capturing pixel, and a second distance between centroids between the centroid of the opening portion of the second image capturing pixel and the centroid of the opening portion of the third image capturing pixel falls within 10% of the first distance between centroids.

### [Additional Statement 20]

The radiation detection sensor according to Additional Statement 19,
in which a fourth image capturing pixel being an image capturing pixel with the second shape is provided in a predetermined column of the third row, and a distance between the centroid of the opening portion of the third image capturing pixel and a centroid of an opening portion of the fourth image capturing pixel is a third distance between centroids, and
in which a difference between the second distance between centroids and the third distance between centroids falls within 10% of the second distance between centroids.

### [Additional Statement 21]

The radiation detection sensor according to Additional Statement 18, in which a first distance between centroids between the centroid of the opening portion of the first image capturing pixel and the centroid of the opening portion of the second image capturing pixel is shorter than a second distance between centroids between the centroid of the opening portion of the second image capturing pixel and the centroid of the opening portion of the third image capturing pixel.

### [Additional Statement 22]

A radiation detection sensor comprising:
a pixel matrix in which a plurality of pixels, each including a conversion element that converts radiation or light into a charge, and a switch element, is arranged in a matrix, the pixel matrix including a plurality of image capturing pixels to be used for acquisition of a radiographic image, and a plurality of detection pixels to be used for detection of a dose of radiation;
a plurality of first drive lines for driving switch elements of the plurality of image capturing pixels included in the pixel matrix; and
a plurality of second drive lines for driving switch elements of the plurality of detection pixels included in the pixel matrix;
in which a first row of the pixel matrix includes a first image capturing pixel serving as the image capturing pixel, the detection pixel, the first drive line, and the second drive line,
in which a second row of the pixel matrix includes a second image capturing pixel serving as the image capturing pixel, and the first drive line, and includes neither the detection pixel nor the second drive line,
in which the second drive line is configured to exert influence in a direction of bringing a centroid position of an opening portion of the first image capturing pixel closer to a nearest first drive line than to a centroid position of an opening portion of the second image capturing pixel, and
in which a shape of the opening portion of the first image capturing pixel is a shape for cancelling at least part of the influence in the direction of bringing the centroid position closer, and is a shape different from a shape of the opening portion of the second image capturing pixel.

### [Additional Statement 23]

The radiation detection sensor according to Additional Statement 22, in which the shape of the opening portion of the first image capturing pixel differs from the shape of the opening portion of the second image capturing pixel by a shape of the conversion element or a shape of a light shielding portion covering a part of the conversion element.

### [Additional Statement 24]

A radiation imaging apparatus comprising:
a plurality of pixels arrayed in a matrix to acquire a radiographic image; and
a drive circuit configured to control the plurality of pixels via a plurality of drive lines,
in which the plurality of pixels includes a plurality of first pixels for acquiring the radiographic image, and a plurality of second pixels for acquiring irradiation information of radiation aside from the radiographic image,
in which the plurality of drive lines includes a plurality of first drive lines arranged to drive first pixels arrayed in a same pixel row among the plurality of first pixels, and a plurality of second drive lines arranged to drive second pixels arrayed in a same pixel row among the plurality of second pixels,
in which the drive circuit has an operation mode of simultaneously driving a predetermined number of first drive lines of the plurality of first drive lines, the predetermined number being two or more,
in which the plurality of second drive lines includes two second drive lines between which no other second drive line is arranged, and
in which a number of first drive lines arranged between the two second drive lines among the plurality of first drive lines is a positive integer multiple of the predetermined number.

### [Additional Statement 25]

The radiation imaging apparatus according to Additional Statement 24, in which the drive circuit does not drive the plurality of second drive lines in the operation mode.

### [Additional Statement 26]

The radiation imaging apparatus according to Additional Statement 24 or 25, in which the drive circuit simultaneously drives the predetermined number of consecutively-arranged first drive lines among the plurality of first drive lines in the operation mode.

### [Additional Statement 27]

The radiation imaging apparatus according to any one of Additional Statements 24 to 26, in which the operation mode is used when signals are read out from the plurality of first pixels after emission of radiation.

### [Additional Statement 28]

The radiation imaging apparatus according to any one of Additional Statements 24 to 27, in which the operation mode is used when a radiation emission start is detected.

### [Additional Statement 29]

The radiation imaging apparatus according to any one of Additional Statements 24 to 28, in which the drive circuit makes a number of first drive lines to be simultaneously driven among the plurality of first drive lines different between a time of detecting a radiation emission start and a time of reading out signals from the plurality of first pixels after emission of radiation.

### [Additional Statement 30]

The radiation imaging apparatus according to any one of Additional Statements 1 to 6,
in which the drive circuit has an operation mode different from the operation mode in which two or more first drive lines of the plurality of first drive lines are simultaneously driven, a number of two or more first drive lines being a different number from the predetermined number, and
in which a number of first drive lines arranged between the two second drive lines of the plurality of first drive lines is a common multiple of the predetermined number and the different number.

### [Additional Statement 31]

The radiation imaging apparatus according to any one of Additional Statements 24 to 30, in which the drive circuit drives the plurality of second drive lines during emission of radiation.

### [Additional Statement 32]

The radiation imaging apparatus according to any one of Additional Statements 24 to 31, in which the plurality of first drive lines and the plurality of second drive lines are connected to a same drive circuit.

### [Additional Statement 33]

The radiation imaging apparatus according to any one of Additional Statements 24 to 31, in which the drive circuit includes a first drive circuit to which the plurality of first drive lines is connected, and a second drive circuit to which the plurality of second drive lines is connected.

### [Additional Statement 34]

The radiation imaging apparatus according to any one of Additional Statements 24 to 33, in which each of the plurality of pixels includes a switch element, and a conversion element that converts incident radiation into an electrical signal and that is connected to any drive line of the plurality of drive lines via the switch element.

### [Additional Statement 35]

A radiation imaging system comprising:
a radiation imaging apparatus according to any one of Additional Statements 24 to 34; and
a signal processing unit configured to process a signal output from the radiation imaging apparatus.

While the present disclosure has been described with reference to embodiments, it is to be understood that the present disclosure is not limited to the disclosed embodiments. The scope of the following claims is to be accorded the broadest interpretation so as to encompass all such modifications and equivalent structures and functions.

This application claims the benefit of Japanese Patent Applications No. 2024-123114, filed Jul. 30, 2024, No. 2024-154233, filed Sep. 6, 2024, and No. 2025-040486, filed Mar. 13, 2025, which are hereby incorporated by reference herein in their entirety.

What is claimed is:

1. A radiation detector comprising:
a pixel matrix including a plurality of pixels arranged in a matrix, each including a conversion element that converts radiation or light into a charge, and a switch element, the pixel matrix including a plurality of image capturing pixels to be used for acquisition of a radiographic image, and a plurality of detection pixels to be used for detection of a dose of radiation;
a plurality of first drive lines for driving switch elements of the plurality of image capturing pixels, the plurality of first drive lines extending along a row direction of the matrix; and
a plurality of second drive lines for driving switch elements of the plurality of detection pixels, the plurality of second drive lines extending along the row direction,
wherein a first pixel row of the pixel matrix is a pixel row that is neighbored by the first drive line and also by the second drive line,
wherein an average area of an opening portion of the image capturing pixel included in the first pixel row and an opening portion of the detection pixel is a first average area, and
wherein an error of an area of each opening portion of all image capturing pixels and all detection pixels included in the first pixel row falls within 1% of the first average area.

2. The radiation detector according to claim 1, wherein the image capturing pixel has a first shape for connecting the first drive line to the switch element, and the detection pixel has a second shape for connecting the second drive line to the switch element.

3. The radiation detector according to claim 1, wherein the first drive line is provided on an opposite side of the second drive line across the first pixel row sandwiched therebetween.

4. The radiation detector according to claim 1, wherein a line width of the second drive line is thinner than a line width of the first drive line.

5. The radiation detector according to claim 1, wherein the opening portion is a region of the conversion element that excludes a region shielded by a light shielding portion.

6. A radiation detector comprising:
a pixel matrix including a plurality of pixels arranged in a matrix, each including a conversion element that converts radiation or light into a charge, and a switch element, each including a conversion element that converts radiation or light into a charge, and a switch element, is arranged in a matrix, the pixel matrix including a plurality of image capturing pixels to be used for acquisition of a radiographic image, and a plurality of detection pixels to be used for detection of a dose of radiation;
a plurality of first drive lines for driving switch elements of the plurality of image capturing pixels, the plurality of first drive lines extending along a row direction of the matrix; and
a plurality of second drive lines for driving switch elements of the plurality of detection pixels, the plurality of second drive lines extending along the row direction,
wherein a first pixel row of the pixel matrix is a pixel row that is neighbored by the first drive line and also by the second drive line,
wherein a second pixel row of the pixel matrix is a pixel row arranged adjacent to the first pixel row, the second pixel row being a pixel row that is neighbored by the first drive line but is not neighbored by the second drive line,
wherein a third pixel row of the pixel matrix is a pixel row arranged adjacent to the second pixel row, the third pixel row being a pixel row that is neighbored by the first drive line but is not neighbored by the second drive line,
wherein the image capturing pixel of the first pixel row, the image capturing pixel of the second pixel row, and the image capturing pixel of the third pixel row, which are three image capturing pixels arrayed in a predetermined column of the pixel matrix, respectively has a first centroid position, a second centroid position, and a third centroid position as centroid positions of respective opening portions, and
wherein a distance between the first centroid position and the second centroid position is a first distance between centroids, a distance between the second centroid position and the third centroid position is a second distance between centroids, and a difference between the first distance between centroids and the second distance between centroids is a distance falling within 10% of the second distance between centroids.

7. The radiation detector according to claim 6, wherein the image capturing pixel has a first shape for connecting the first drive line to the switch element, and the detection pixel has a second shape for connecting the second drive line to the switch element.

8. The radiation detector according to claim 6, wherein the first drive line is provided on an opposite side of the second drive line across the first pixel row sandwiched therebetween.

9. The radiation detector according to claim 6, wherein a first distance between centroids is shorter than a second distance between centroids.

10. The radiation detector according to claim 6, wherein a size of a gap generated between the first image capturing pixel and the second image capturing pixel falls within 50% of a first distance between centroids.

11. The radiation detector according to claim 6, wherein a line width of the second drive line is thinner than a line width of the first drive line.

12. The radiation detector according to claim 6, wherein the opening portion is a region of the conversion element that excludes a region shielded by a light shielding portion.

13. A radiation imaging apparatus comprising:
a plurality of pixels arrayed in a matrix to acquire a radiographic image; and
a drive circuit configured to control the plurality of pixels via a plurality of drive lines,
wherein the plurality of pixels includes a plurality of first pixels for acquiring the radiographic image, and a plurality of second pixels for acquiring irradiation information of radiation aside from the radiographic image,
wherein the plurality of drive lines includes a plurality of first drive lines arranged to drive first pixels arrayed in a same pixel row among the plurality of first pixels, and a plurality of second drive lines arranged to drive second pixels arrayed in a same pixel row among the plurality of second pixels,
wherein the drive circuit has an operation mode of simultaneously driving a predetermined number of first drive lines of the plurality of first drive lines, the predetermined number being two or more,
wherein the plurality of second drive lines includes two second drive lines between which no other second drive line is arranged, and
wherein a number of first drive lines arranged between the two second drive lines among the plurality of first drive lines is a positive integer multiple of the predetermined number.
